(19) United States
(12) Patent Application Publication
(10) Pub. No.: US 2024/0247376 A1
(43) Pub. Date: Jul. 25, 2024

(54) Fluorinated Aluminum Coated Component for a Substrate Processing Apparatus and Method of Producing

(71) Applicant: Applied Materials, Inc., Santa Clara, CA (US)

(72) Inventors: Douglas LONG, Sunnyvale, CA (US); Jallepally RAVI, San Ramon, CA (US); Dien-yeh WU, San Jose, CA (US)

(21) Appl. No.: 18/416,304

(22) Filed: Jan. 18, 2024

Related U.S. Application Data
(60) Provisional application No. 63/440,316, filed on Jan. 20, 2023.

(51) Int. Cl. C23C 16/455; C23C 4/08; C23C 4/134; C23C 16/42; C23C 16/50; C23C 18/16; C23C 18/31; C25D 3/44; C25D 5/48; H01L 21/285; H01L 21/687

(52) U.S. Cl. CPC C23C 16/45565; C23C 4/08; C23C 4/134; C23C 16/42; C23C 16/50; C23C 18/1689; C23C 18/31; C25D 3/44; C25D 5/48; H01L 21/28518; H01L 21/68757

(57) ABSTRACT

A component of an apparatus for processing a substrate having a coating comprising fluorinated aluminum disposed on at least a portion of a surface of the component. A method of coating the component, a method of repairing a coating on a component, and a method of processing a substrate are also disclosed.

### CROSS-REFERENCE TO RELATED APPLICATIONS

This application claims benefit of U.S. provisional patent application Ser. No. 63/440,316, filed Jan. 20, 2023, which is herein incorporated by reference in its entirety.

### FIELD

Embodiments of the present disclosure generally relate to components of an apparatus for processing a substrate, in particular, to a protective coating for components of an apparatus for processing a substrate.

### BACKGROUND

Substrates utilized in semiconductor devices are processed in a number of different ways under a variety of conditions. The inventors have observed that certain higher temperature plasma processes result in accelerated wear and other damage to components of the apparatus used to process the substrate. In particular the plasma-based deposition of various metal silicides e.g., titanium silicide, involves the use of relatively high temperatures, plasmas comprising halogens e.g., chlorine and fluorine, forming a corrosive environment, which have been observed to require frequent removal, reconditioning, and/or replacement.

### SUMMARY

In an embodiment, a component of an apparatus for processing a substrate comprises a coating comprising fluorinated aluminum disposed on at least a portion of a surface of the component.

In embodiments, a method of coating a component of an apparatus for processing a substrate comprises disposing a coating comprising metallic aluminum on an outer surface of the component; and contacting the metallic aluminum with a fluorinating agent under conditions sufficient to form a fluorinated aluminum coating over at least a portion of the component.

In embodiments, a method of repairing a coating of a component comprises removing at least a portion of an existing coating from the component; disposing a coating comprising metallic aluminum on an outer surface of the component; and contacting the metallic aluminum with a fluorinating agent under conditions sufficient to form a fluorinated aluminum coating over at least a portion of the component.

In embodiments, a method to process a substrate comprises disposing the substrate within a processing volume of a process chamber of an apparatus for processing the substrate, wherein at least one component of the apparatus for processing the substrate comprises a coating comprising fluorinated aluminum disposed on at least a portion of a surface of the component such that the surface is disposed within or faces the processing volume; and processing the substrate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a simplified diagram of an apparatus for processing a substrate according to embodiments disclosed herein.

FIG. 2 is a flowchart depicting a method of coating a component according to embodiments disclosed herein.

FIG. 3 is a flowchart depicting a method of repairing or reapplying a coating of a component according to embodiments disclosed herein.

FIG. 4 is a flowchart depicting a method of treating a substrate according to embodiments disclosed herein.

FIG. 5 is a block diagram depicting a component having a fluorinated aluminum coating according to embodiments disclosed herein.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The high temperature conditions of some deposition and other treatment processes require components of a process chamber of an apparatus for processing a substrate to be formed from nickel, nickel alloys, and/or various ferrous alloys such as stainless or austenitic steels. The applicants have observed that aluminum fluoride is more resistant to chlorine and fluorine attack at high temperatures and/or under plasma conditions, compared to traditional materials such as nickel, aluminum oxide or aluminum nitride. However, components coated with aluminum fluoride via chemical vapor deposition (CVD) and/or atomic layer deposition (ALD) processes were not observed to provided improved levels of resistance to chlorine and fluorine attack under high temperatures, plasmas, and other corrosive process conditions.

Due to the low melting point of aluminum, the various components of the apparatus for processing the substrate are machined out of an appropriate high temperature material such as stainless steel, nickel, or a nickel alloy, then coated with a relatively thin metallic aluminum layer. The aluminum coated component is then subjected to a fluorination process wherein a portion of the aluminum layer is converted into a fluorinated aluminum.

The fluorinated aluminum coating, which in embodiments comprises aluminum fluoride, and in some embodiments consists essentially of aluminum and aluminum fluoride, has been observed to have a much higher melting point than aluminum and greatly improved corrosion resistance as compared to other coatings, and to the underlying component prior to coating. The chemical bonds which form the fluorinated aluminum coating are theorized to be strong, thus providing for improved temperature and corrosion resistance.

In embodiments, a component of an apparatus for processing a substrate comprises a coating comprising fluorinated aluminum disposed on at least a portion of a surface of the component. In embodiments, the coating comprises an inner portion in contact with the surface of the component comprising metallic aluminum and an outer portion forming the outer surface comprising fluorinated aluminum.

In embodiments, the inner portion has a thickness of greater than or equal to about 1 μm, and the outer portion has a thickness of less than or equal to about 2 μm. In embodiments, the coating comprises aluminum trifluoride.

In embodiments, the component comprises nickel and/or a ferrous alloy. In embodiments, the component is a component of an apparatus for processing a substrate, such as a semiconductor or other substrate used in the fabrication of microelectronic devices or other thin film fabrication processes, and/or a semiconductor device.

In embodiments, a method of coating a component of an apparatus for processing a substrate comprises disposing a coating comprising metallic aluminum on an outer surface of the component; and contacting the metallic aluminum with a fluorinating agent under conditions sufficient to form a fluorinated aluminum coating over at least a portion of the component. In embodiments, the fluorinated aluminum coating comprises aluminum trifluoride. In embodiments, the disposing of the coating comprising metallic aluminum on the outer surface of the component comprises electroplating the component.

In embodiments, a method of repairing and/or recoating of a component comprises removing at least a portion of the previously existing coating currently present on the component, when present; disposing a coating comprising metallic aluminum on an outer surface of the component; and contacting the metallic aluminum with a fluorinating agent under conditions sufficient to form a fluorinated aluminum coating over at least a portion of the component.

In embodiments, a method to process a substrate comprises disposing the substrate within a processing volume of a process chamber of an apparatus for processing the substrate, wherein at least one component of the apparatus for processing the substrate comprises a coating comprising fluorinated aluminum disposed on at least a portion of a surface of the component such that the surface is disposed within or faces the processing volume; and processing the substrate. In embodiments, the processing of the substrate comprises plasma deposition of titanium silicide. In embodiments, the component comprising a coating comprising fluorinated aluminum disposed on at least a portion of a surface of the component is a showerhead, an internal portion of the apparatus, a chamber liner, a substrate support structure, a deposition ring, a cover ring, an encasement of a heater, a portion of a gas delivery system present within the apparatus, a pumping channel, or the like.

In embodiments, the aluminum layer is fluorinated by contacting the article coated with aluminum at a temperature, a pressure, and for a period of time to allow the fluorine to react with the aluminum to form an outer coating or layer of fluorinated aluminum.

In embodiments, a high temperature material such as nickel, a nickel alloy, stainless steel, or an austenitic steel, will first be coated with a high purity aluminum base layer, having a purity of greater than or equal to about 95 wt % aluminum. The aluminum coating will then be converted to a passivated aluminum fluoride form.

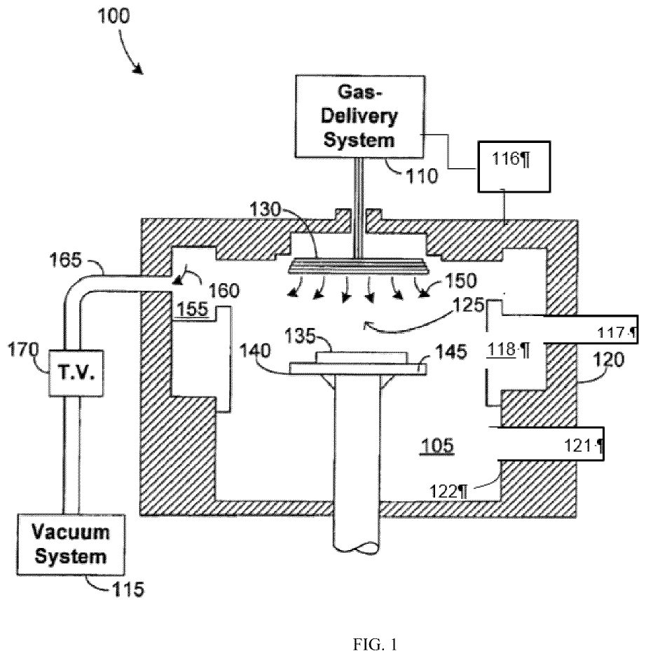

FIG. 1 depicts a simplified diagram of an exemplary apparatus 100 for processing a substrate, illustrating the basic structure of a chamber in which individual deposition steps, and other steps can be performed. The apparatus 100 is illustratively suitable for performing thermal, sub-atmospheric CVD processes, as well as other processes, such as reflow, drive-in, cleaning, etching, deposition, and gettering processes. In some instances, multiple-step processes can still be performed within an individual chamber before removal for transfer to another chamber. The major components of the system include, among others, a vacuum chamber 105 that receives process and other gases from a gas delivery system 110, a vacuum system 115, and a control system 116. In embodiments, the apparatus may comprise an internal or external source 117 of a plasma 118 utilized during processing of substrate. While the drawing shows the structure of only a single chamber for purposes of illustration, multiple chambers with similar structures may be provided as part of a cluster tool, each tailored to perform different aspects of certain overall fabrication processes.

The apparatus 100 includes an enclosure assembly 120 that forms vacuum chamber 105 with a process volume 125. A gas distribution structure, such as showerhead 130, disperses reactive gases and other gases, such as purge gases, toward one or more substrates 135 held in position by a substrate support structure 140. Heaters 145 can be controllably moved between different positions to accommodate different deposition processes as well as for an etch or cleaning process.

Reactive and carrier gases are supplied from gas delivery system 110 through supply lines to the showerhead 130. The supply lines deliver gases to the gas distribution structure separately, as described below. Gas delivery system 110 includes a variety of gas sources and appropriate supply lines to deliver a selected amount of each source to vacuum chamber 105. Generally, supply lines for each of the gases include shut-off valves that can be used to automatically or manually shut-off the flow of the gas into an associated supply line, and mass flow controllers or other types of controllers that measure the flow of gas or liquid through the supply lines. Depending on the process run by the system, some of the sources may be liquid sources rather than gases. When liquid sources are used, gas delivery system 110 includes a liquid injection system or other appropriate mechanism (e.g., a bubbler) to vaporize the liquid. Vapor from the liquids is then usually mixed with a carrier gas. During deposition processing, gas supplied to the showerhead 130 flows toward the substrate surface (as indicated by arrows 150), where the gas may be uniformly distributed radially across the substrate surface in a laminar flow.

Purging gas may be delivered into the vacuum chamber 105 from showerhead 130 and/or from inlet ports 121 disposed through a wall 122 of enclosure assembly 120. Purge gas introduced into the vacuum chamber 105 flows to an annular pumping channel 155. Vacuum system 115 which includes a vacuum pump, exhausts the gas (as indicated by arrows 160) through an exhaust line 165. The rate at which exhaust gases and entrained particles are drawn from the annular pumping channel 155 through the exhaust line 165 is controlled by a throttle valve system 170.

In embodiments, one or more of these components, e.g., a portion of the enclosure assembly 120, the showerhead 130, the substrate support structure 140, the encasement of the heaters 145, portions of the gas delivery system 110 present within the vacuum chamber 105, annular pumping channel 155, and/or the like, may comprise a coating comprising fluorinated aluminum disposed on at least a portion of a surface of the component.

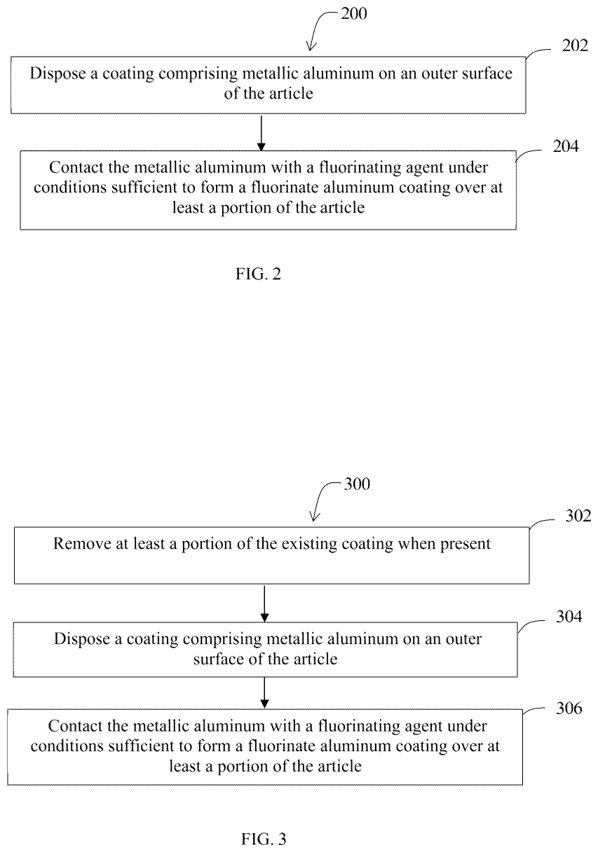

FIG. 2 is a flowchart of an example process 200 of coating a component of an apparatus for processing a substrate. As shown in FIG. 2, process 200 may include disposing a coating having metallic aluminum on an outer surface of the component of an apparatus for processing a substrate (block 202). As also shown in FIG. 2, process 200 may include contacting the metallic aluminum with a fluorinating agent under conditions sufficient to form a fluorinated aluminum coating over at least a portion of the component (block 204).

In embodiments, the disposing of the metallic aluminum on the outer surface of the component comprises electrolytic deposition, e.g., electroplating. Other suitable methods of disposing the metallic aluminum on the outer surface of the component include electroless immersion, plasma spray, and the like.

Although FIG. 2 shows example blocks of process 200, in some implementations, process 200 may include additional blocks than those depicted in FIG. 2. Additionally, or alternatively, two or more of the blocks of process 200 may be performed in parallel.

FIG. 3 is a flowchart of an example process 300 of a method of repairing and/or replacing a coating of a component of an apparatus for processing a substrate.

The method depicted in FIG. 3 may be performed in individual process chambers provided as a standalone chamber or as part of a cluster tool. In embodiments, a cluster tool is configured for performing the methods for processing a substrate as described herein.

As shown in FIG. 3, process 300 may include removing at least a portion of an existing coating, when present (block 302). For example, the processing chamber or cluster tool may remove at least a portion of the coating which was previously disposed on an outer side of the component. As also shown in FIG. 3, process 300 may include disposing a coating having metallic aluminum on an outer surface of the component (block 304). As further shown in FIG. 3, process 300 may include contacting the metallic aluminum with a fluorinating agent under conditions sufficient to form a fluorinated aluminum coating over at least a portion of the component (block 306).

Although FIG. 3 shows example blocks of process 300, in some implementations, process 300 may include additional blocks, fewer blocks, different blocks, or differently arranged blocks than those depicted in FIG. 3. Additionally, or alternatively, two or more of the blocks of process 300 may be performed in parallel.

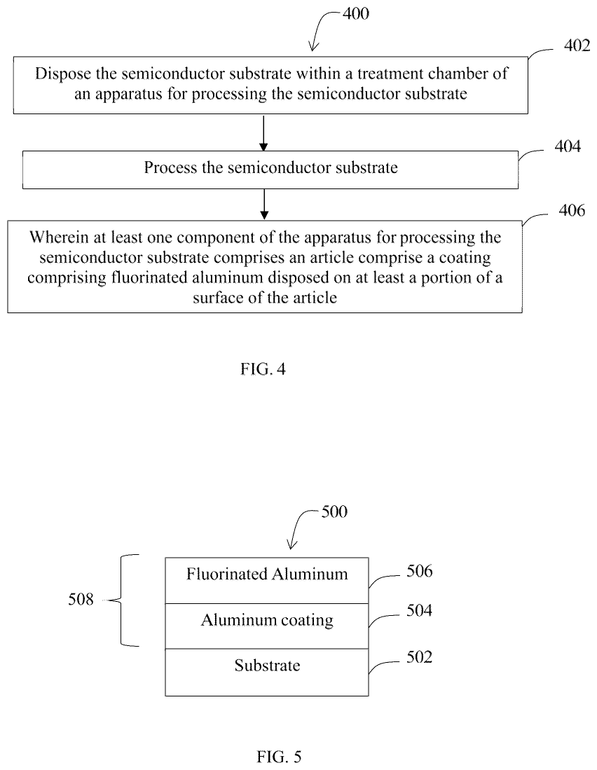

FIG. 4 is a flowchart of an example process 400 of a method to process a substrate. The method depicted in FIG. 4 may be performed in individual process chambers provided as a standalone process chamber or as part of a cluster tool. In embodiments, a cluster tool is configured for performing the methods for processing a substrate as described herein.

As shown in FIG. 4, process 400 may include disposing the substrate within a process chamber of an apparatus for processing the substrate, (block 402). As also shown in FIG. 4, process 400 may include processing the substrate (block 404). As further shown in FIG. 4, process 400 includes at least one component of the apparatus for processing the substrate includes a coating having fluorinated aluminum disposed on at least a portion of a surface of the component (block 406). In embodiments, the processing the substrate comprises plasma deposition of a metal silicide, which in embodiments may be titanium silicide.

Although FIG. 4 shows example blocks of process 400, in some implementations, process 400 may include additional blocks, fewer blocks, different blocks, or differently arranged blocks than those depicted in FIG. 4. Additionally, or alternatively, two or more of the blocks of process 400 may be performed in parallel.

FIG. 5 depicts a block diagram of a component of an apparatus for processing a substrate 500, comprising the component 502 having a coating 508 comprising an inner portion 504 in contact with the surface of the component comprising metallic aluminum and an outer portion 506 forming the outer surface which has been fluorinated and comprises fluorinated aluminum.

In embodiments, the coating 508 has an inner portion 504 having a thickness of greater than or equal to about 1 μm, or greater than or equal to about 2 μm, or greater than or equal to about 3 μm, or greater than or equal to about 4 μm, or greater than or equal to about 5 μm, or greater than or equal to about 6 μm, or greater than or equal to about 7 μm, or greater than or equal to about 8 μm, or greater than or equal to about 10 μm, and an outer portion 506 having a thickness of less than or equal to about 5 μm, less than or equal to about 3 μm, or less than or equal to about 2 μm, or less than or equal to about 1.5 μm, or less than or equal to about 1 μm, or less than or equal to about 0.5 μm. In embodiments, the coating 508 comprises aluminum and aluminum trifluoride, consists essentially of aluminum and aluminum fluoride, or consists of aluminum and aluminum fluoride.

In embodiments, the coating 508 is formed from a layer of aluminum i.e., the aluminum coating of the inner portion 504 comprises, consists of or consists essentially of aluminum having a purity of greater than or equal to about 95 wt %, or greater than or equal to about 98 wt %, or greater than or equal to about 99 wt %, or greater than or equal to about 99.5 wt %, or greater than or equal to about 99.995 wt %, based on the total amount of the layer present prior to fluorinating.

In other embodiments, the coating 508 is formed from a layer of an aluminum allow, i.e., the aluminum coating of the inner portion 504 comprises, consists of or consists essentially of an aluminum alloy, which are formed predominantly from aluminum, but may further comprise copper, magnesium, manganese, silicon, tin, nickel, zinc, niobium, and the like. Suitable aluminum alloys include aluminum 1000 series alloys, aluminum 2000 series alloys, aluminum 3000 series alloys, aluminum 4000 series alloys, aluminum 5000 series alloys, aluminum 6000 series alloys, aluminum 7000 series alloys, and aluminum 8000 series alloys.

In embodiments, the component is a component of an apparatus for processing a substrate and/or a semiconductor device such as described above.

Embodiments in accordance with the instant disclosure include, but are not limited to, the following.

E1. A component of an apparatus for processing a substrate, comprising:
a coating comprising fluorinated aluminum disposed on at least a portion of a surface of the component.

E2. The component according to Embodiment E1, wherein the coating comprises an inner portion in contact with the surface of the component comprising metallic aluminum and an outer portion forming an outer surface comprising fluorinated aluminum.

E3. The component according to Embodiments E1-E2, wherein the inner portion has a thickness of greater than or equal to about 1 μm, and the outer portion has a thickness of less than or equal to about 2 μm.

E4. The component according to Embodiments E1-E3, wherein the coating comprises aluminum trifluoride.

E5. The component according to Embodiments E1-E4, wherein the component comprises nickel and/or a ferrous alloy.

E6. The component according to Embodiments E1-E5, wherein the component is a component of an apparatus for processing a substrate and/or a semiconductor device.

E7. A method of coating a component of an apparatus for processing a substrate according to Embodiments E1-E6, comprising:
disposing a coating comprising metallic aluminum on an outer surface of the component; and
contacting the metallic aluminum with a fluorinating agent under conditions sufficient to form a fluorinated aluminum coating over at least a portion of the component.

E8. A method of coating a component of an apparatus for processing a substrate, comprising:
disposing a coating comprising metallic aluminum on an outer surface of the component; and
contacting the metallic aluminum with a fluorinating agent under conditions sufficient to form a fluorinated aluminum coating over at least a portion of the component.

E9. The method according to Embodiments E7-E8, wherein the fluorinated aluminum coating comprises aluminum trifluoride.

E10. The method according to Embodiments E7-E9, wherein disposing the coating comprising metallic aluminum on the outer surface of the component comprises electroplating the component.

E11. A method of repairing a coating of a component, comprising:
removing at least a portion of an existing coating present on an outer surface of the component from the component; and
coating the component according to the method of Embodiments E7-E10.

E12. A method of repairing a coating of a component, comprising:
removing at least a portion of an existing coating present on an outer surface of the component from the component;
disposing a coating comprising metallic aluminum on an outer surface of the component; and
contacting the metallic aluminum with a fluorinating agent under conditions sufficient to form a fluorinated aluminum coating over at least a portion of the component.

E13. A method of processing a substrate, comprising:
disposing the substrate within a processing volume of a process chamber of an apparatus for processing the substrate, wherein at least one component of the apparatus for processing the substrate is according to Embodiments E1-E6.

E14. A method of processing a substrate, comprising:
disposing the substrate within a processing volume of a process chamber of an apparatus for processing the substrate, wherein at least one component of the apparatus for processing the substrate comprises a coating disposed according to Embodiments E7-E12.

E15. A method of processing a substrate, comprising:
disposing the substrate within a processing volume of a process chamber of an apparatus for processing the substrate, wherein at least one component of the apparatus for processing the substrate comprises a coating comprising fluorinated aluminum disposed on at least a portion of a surface of the component such that the surface is disposed within or faces the processing volume; and
processing the substrate.

E16. The method according to Embodiments E13-E15, wherein the processing the substrate comprises plasma deposition of titanium silicide.

E17. The method according to Embodiments E13-E16, wherein the component comprising a coating comprising fluorinated aluminum is disposed on at least a portion of a surface of the component is a showerhead.

While the foregoing is directed to embodiments of the present disclosure, other and further embodiments of the disclosure may be devised without departing from the basic scope thereof.

1. A component of an apparatus for processing a substrate, comprising:
a coating comprising fluorinated aluminum disposed on at least a portion of a surface of the component.

2. The component of claim 1, wherein the coating comprises an inner portion in contact with the surface of the component comprising metallic aluminum and an outer portion forming an outer surface comprising fluorinated aluminum.

3. The component of claim 2, wherein the inner portion has a thickness of greater than or equal to about 1 μm, and the outer portion has a thickness of less than or equal to about 2 μm.

4. The component of an apparatus for processing a substrate of claim 1, wherein the coating comprises aluminum trifluoride.

5. The component of claim 1, wherein the component comprises nickel and/or a ferrous alloy.

6. The component of claim 1, wherein the component is a component of an apparatus for processing a substrate and/or a semiconductor device.

7. A method of coating a component of an apparatus for processing a substrate, comprising:
disposing a coating comprising metallic aluminum on an outer surface of the component; and
contacting the metallic aluminum with a fluorinating agent under conditions sufficient to form a fluorinated aluminum coating over at least a portion of the component.

8. The method of claim 7, wherein the fluorinated aluminum coating comprises aluminum trifluoride.

9. The method of claim 7, wherein disposing the coating comprising metallic aluminum on the outer surface of the component comprises electroplating the component.

10. The method of claim 7, further comprising removing at least a portion of an existing coating present on an outer surface of the component from the component prior to disposing a coating comprising metallic aluminum on an outer surface of the component; and
contacting the metallic aluminum with a fluorinating agent under conditions sufficient to form a fluorinated aluminum coating over at least a portion of the component.

11. A method of processing a substrate, comprising:
disposing the substrate within a processing volume of a process chamber of an apparatus for processing the substrate, wherein at least one component of the apparatus for processing the substrate comprises a coating comprising fluorinated aluminum disposed on at least a portion of a surface of the component such that the surface is disposed within or faces the processing volume; and
processing the substrate.

12. The method of claim 11, wherein the processing the substrate comprises plasma deposition of titanium silicide.

13. The method of claim 11, wherein the component comprising a coating comprising fluorinated aluminum disposed on at least a portion of a surface of the component is a showerhead.

14. The component of claim 2, wherein the inner portion comprises metallic aluminum having a purity of greater than or equal to about 95 wt % aluminum.

15. The component of claim 1, wherein the component comprises stainless steel.

16. The component of claim 1, wherein the component comprises an austenitic steel.

17. The method of claim 7, wherein disposing the coating comprising metallic aluminum on the outer surface of the component comprises electroless immersion.

18. The method of claim 7, wherein disposing the coating comprising metallic aluminum on the outer surface of the component comprises plasma spray.

19. The method of claim 11, wherein the component comprising a coating comprising fluorinated aluminum disposed on at least a portion of a surface of the component is an enclosure assembly, a showerhead, a substrate support structure, an encasement of a heater, a portion of a gas delivery system present within a vacuum chamber, or an annular pumping channel.

20. The method of claim 11, wherein the component comprising a coating comprising fluorinated aluminum disposed on at least a portion of a surface of the component is a substrate support structure.
